(19) United States
(12) Patent Application Publication
(10) Pub. No.: US 2011/0051485 A1
(43) Pub. Date: Mar. 3, 2011

(54) CONTENT ADDRESSABLE MEMORY ARRAY WRITING

(75) Inventors: Leland Chang, Yorktown Heights, NY (US); Gary S. Ditlow, Yorktown Heights, NY (US); Brian L. Ji, Chappaqua, NY (US); Robert K. Montoye, Yorktown Heights, NY (US)

(73) Assignee: INTERNATIONAL BUSINESS MACHINES CORPORATION, Armonk, NY (US)

(21) Appl. No.: 12/549,761

(22) Filed: Aug. 28, 2009

(51) Int. Cl. G11C 15/00; G11C 7/00; G11C 11/00

(52) U.S. Cl. 365/49.17; 365/189.2; 365/49.1; 365/163

(57) ABSTRACT

A memory system for storing one or more addresses includes a transposable memory having word lines, bit lines, transposed word lines and transposed bit lines and that receives and stores an input array having dimensions M by N and a content addressable memory (CAM) that reads the transposed word lines of the transposable memory to form input words and that stores the input words in an N by M array.

### BACKGROUND

The present invention relates to memory devices, and more specifically, to content addressable memory devices.

Random access memory (RAM) associates data with an address. Volatile RAMs such as dynamic RAM (DRAM) and static RAM (SRAM) are traditionally used in today's computers. However, as wireless mobile computing systems become more popular, intensive research and development in the memory area is now focusing on new non-volatile memories. Important non-volatile RAMs known today are ferroelectric RAM (FeRAM) using non-linear capacitance due to different polarization of the lead-zirconium-titanate (PZT) material, magnetic RAM (MRAM) using the magneto-resistance changes with magnetic polarity, and Chalcogenide phase change materials using resistance changes in ordered (conductive) and disordered (resistive) phases.

Content-addressable memory (CAM) is a special type of computer memory used in certain very high speed searching applications. It is also known as associative memory or associative storage. Most existing CAM products are volatile technologies based on SRAM or DRAM cells. CAMS using resistance-change memory element such as, for example, Chalcogenide phase change materials, have been found to allow for density improvements in the formation of a CAM.

Unlike standard computer memory (e.g., RAM) in which the user supplies a memory address and the RAM returns the data word stored at that address, a CAM is designed such that the user supplies a data word and the CAM searches its entire memory to see if that data word is stored anywhere in it. If the data word is found, the CAM returns a list of one or more storage addresses where the word was found (and in some architectures, it also returns the data word, or other associated pieces of data). Thus, a CAM is the hardware embodiment of what, in software terms, could be called an associative array.

Binary CAM is the simplest type of CAM which uses data search words comprised entirely of 1s and 0s. Ternary CAM (TCAM) allows a third matching state of “X” or “Don't Care” for one or more bits in the stored dataword, thus adding flexibility to the search. For example, a ternary CAM might have a stored word of “10XX0” which will match any of the four search words “10000”, “10010”, “10100”, or “10110”.

### SUMMARY

According to one embodiment of the present invention, a memory system for storing one or more addresses is provided. The system includes a transposable memory having word lines, bit lines, transposed word lines and transposed bit lines and that receives and stores an input array having dimensions M by N and a content addressable memory (CAM) that reads the transposed word lines of the transposable memory to form input words and that stores the input words in an N by M array.

According to another embodiment of the present invention, a method of writing a content addressable memory is provided. The method includes storing input data in a transposable array, each word of the input data being stored in along a word line; reading a first transposed word line of the transposable array to create a transposed first data word; and storing each bit of the first transposed data word in a separate memory cell of plurality of memory cells arranged along a first write line of the content addressable memory.

According to another embodiment of the present invention, a method of operating a content addressable memory (CAM) is provided. The method includes storing input data in a transposable array; accessing the transposable array to receive a transposed input data array; and storing the transposed input data array in the CAM a word at a time.

Additional features and advantages are realized through the techniques of the present invention. Other embodiments and aspects of the invention are described in detail herein and are considered a part of the claimed invention. For a better understanding of the invention with the advantages and the features, refer to the description and to the drawings.

### BRIEF DESCRIPTION OF THE SEVERAL VIEWS OF THE DRAWINGS

The subject matter which is regarded as the invention is particularly pointed out and distinctly claimed in the claims at the conclusion of the specification. The forgoing and other features, and advantages of the invention are apparent from the following detailed description taken in conjunction with the accompanying drawings in which:

FIG. 1 shows an example of a memory cell for use in a CAM;

FIG. 2 shows an example of a CAM;

FIG. 3 shows a data flow diagram showing the transformation of input array to a transposed array that is written to a CAM according to one embodiment of the present invention; and

FIG. 4 is a flow chart showing a method of writing a CAM according to one embodiment of the present invention.

### DETAILED DESCRIPTION

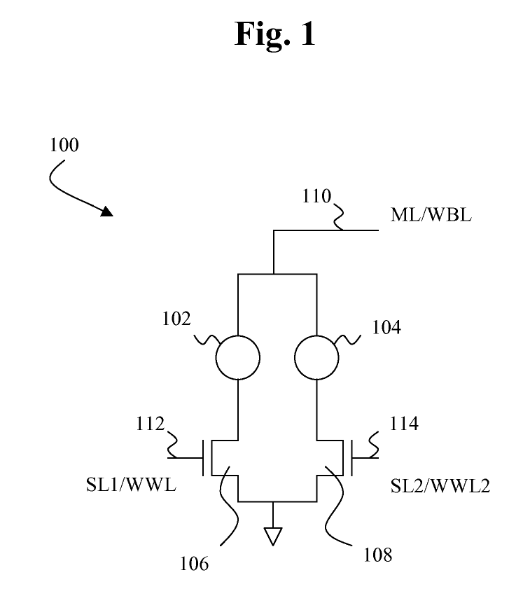

An example of a memory cell 100 for use in a CAM is shown in FIG. 1. The memory cell 100 shown in FIG. 1 may be a ternary CAM cell in one embodiment. The memory cell 100 includes a first memory element 102 and a second memory element 104. The first resistive memory element 102 second memory element 104 are electrically coupled in parallel to a match line 110. The match line 110 may also be utilized as bit-line in some embodiments. The first memory element 102 and the second memory element 104 may be formed as, for example, a phase change memory element. Phase change material can be utilized to store information in CAM devices and, accordingly may be used as the memory elements in some embodiments. Phase change materials can be manipulated into different phases or states, with each phase representing a different data value. Generally, each phase exhibits different electrical properties. The amorphous and crystalline phases are typically two phases used for binary data storage (1's and 0's) since they have detectable differences in electrical resistance. In a particular configuration of the invention, the first and second memory elements are phase change elements comprised of a phase change material, such as Germanium-Antimony-Tellurium (GST). The memory elements may be programmed to one of two states: a crystalline state or an amorphous state. In the crystalline state (SET), the memory elements exhibit relatively low resistances and require less current to be programmed to. On the other hand, in the amorphous state (RESET), the memory elements have relatively high resistances and require more current to be programmed to. The resistance states of the first and second memory elements are used to store a data bit in a data word. For example, to store a data bit with a low ternary data value, the first memory element is programmed to the low resistance state and the second memory element is programmed to the high resistance state.

Other possibilities for the memory elements include, but are not limited to, resistive memory elements, floating gate field effect transistors (floating gate FETs), Magnetoresistive Random Access Memory (MRAMs), or a charge trapping device.

The memory cell 100 includes a first access device 106 electrically coupled to the first memory element 102, a first access line 106 and a common ground. The memory cell 100 also includes a second access device 108 electrically coupled to the second memory element 108, a second access line 114, and the common ground. The first access device 106 and the second access device 108 may be comprised of, but not limited to, field effect transistors (FET), or bipolar junction transistors (BJT). In one configuration of the invention, the access devices 108 and 110 include source, drain and common terminals. The source terminals of the access devices 106 and 108 are electrically coupled together and to the common ground. The drain terminal of the first access device 106 is electrically coupled to the first memory element 102. The drain terminal of the second access device 108 is electrically coupled to the second memory element 104. The gate terminal of the first access device 106 is electrically coupled to the first access line 114, which functions as the word line during the data storage operation. During a search operation, the first access line also functions as the complementary search line. The gate terminal of the second access device 104 is electrically coupled to the second access line 114, which functions as the complementary word line during the data storage operation and as a search line during a search operation.

As shown the memory cell 100 may have 4 possible states based on the programming of the first memory element 102 and second memory element 104. These combinations are RR, Rr, rR, and rr where R is high resistance and r is a low resistance. These combinations may be used to create the states shown below in Table 1 where the cell state X is the so called “don't care” state.

TABLE 1

| | First Element | Second Element |
|---|---|---|
| Cell State | Resistive State | Resistive State |
| X | High | High |
| 0 | High | Low |
| 1 | Low | High |

A method of storing a single bit of information in the memory cell 100 using phase change devices is now described. The data storage operation consists of two steps. To begin with, both the access devices 106 and 108 are in the off state, as the first access line (or write word line) 112 and second access line (complementary write word line 114) are biased at zero volts. In the first step, access device 106 is turned on by applying a voltage pulse at the write word line 112. If the data bit value to be stored is the low state or don't care state, a RESET current pulse is applied to the write bit line (match line) line 110 such that the magnitude of current passing through the first memory element 102 is high enough to melt a critical volume of the chalcogenide alloy. This applied pulse is quickly turned off, to convert the molten volume to the amorphous phase, programming the memory element 102 to a high resistance state. If the data bit value to be stored is the high state, a SET current pulse is applied to the write bit line 110 such that the magnitude of current passing through the first memory element 102 anneals any amorphous region to the poly-crystalline phase of the material, programming the memory element 104 to a low resistance state. During this stage, no current passes through the memory element 104 as the access device 108 is turned off.

In the second step, access device 108 is turned on by applying a voltage pulse at the complementary word line 114. If the data bit value to be stored is the high state or don't care state, a RESET current pulse is applied to the write bit line 110 such that the magnitude of current passing through the second memory element 108 is high enough to melt a critical volume of the chalcogenide alloy. This applied pulse is quickly turned off, to convert the molten volume to the amorphous phase, programming the memory element 108 to a high resistance state. If the data bit value to be stored is the low state, a SET current pulse is applied to the bit line 110 such that the magnitude of current passing through the second memory element 108 anneals any amorphous region to the poly-crystalline phase of the material, programming the second memory element 104 to a low resistance state. During this stage, no current passes through the memory element 102 as the access device 106 is turned off.

Searching for an individual bit may be done as follows. If the search bit value is high, the first access device 106 is set to a low resistance by applying a positive voltage to the complementary search line 112 (SL₁) and the second access device 108 is set to a high resistance by applying zero bias to the search line 114 (SL₂). If the search bit value is low, the first access device 106 is set to a high resistance by applying zero bias to the complementary search line 112 and the second access device 108 is set to a low resistance by applying a positive voltage to the search line 114. If the search bit value is “don't care,” both the first access device 106 and the second access device 108 are set to a high resistance by applying zero bias to the complementary search line 112 and the search line 114.

The search operation is then conducted by applying a small positive bias voltage at the search line (match line) 110, and measuring the resulting current that flows from the search line 110 to ground. It is noted that an appreciably large current (larger than a predetermined baseline current) will pass through the match-line 110 to ground only if either both the first access device 106 and the first memory element 102 are in low resistance states, or both the second access device 108 and the second memory element 104 are in low resistance states. Such conditions indicate a mismatch between the stored bit and the search bit. During a perfect match between the stored data and the search data, no appreciable current can flow from the search line 110 to ground, as the access device connected to the low resistance memory element will be in the off state and the memory element connected to the access device in the low resistance state will be in the high resistance state. Moreover, if both the first and second memory elements 102 and 104 are in high resistance states, an appreciably large current can never flow, indicating that a mismatch condition can never occur. Thus, programming the first and second memory elements 106 and 108 in the high resistance states assigns a don't care value to the memory cell.

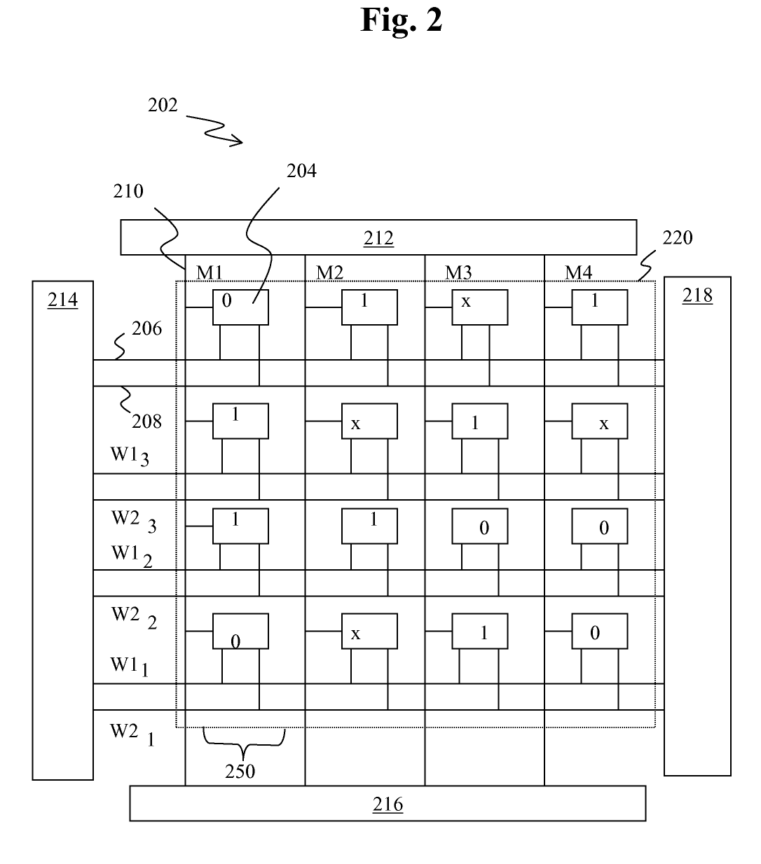

FIG. 2 shows an example of layout of CAM 202 according to one embodiment. The content addressable memory device 202 includes a plurality of memory cells 204 arranged in a content addressable memory array 220, a plurality of word-lines 206, a plurality of complementary word-lines 208, a plurality of match-lines 210, and a match circuit 212. Those skilled in the art will appreciate that under this configuration, the word-lines 206 function also as the complementary search lines during the search operation, complementary word-lines 208 function also as the search-lines and that the match-lines 210 function also as the write bit-lines.

In one embodiment of the invention, the CAM 202 also includes a word-line decoder 214, a bit decoder/data driver 216, and a search driver 218. Each data word in the memory array 220 is comprised of a plurality of memory cells electrically coupled in parallel circuit to an individual match-line 210. Each bit of a data word is set to one of three ternary data values of low, high, and don't care. The low and high data values can store “0” and “1” or “1” and “0” respectively. The don't care value is represented by “X” in the figure. As shown, each individual memory cell 204 is electrically coupled to an individual first word-line 206, an individual second word-line 208, and an individual match-line 210. The word-lines 206 and the complementary word-lines 208 are electrically coupled to the word-lines decoder 214 and the search driver 218. In one embodiment of the invention, the word-line decoder/data driver 214 applies voltage biases to the word-lines 206 and the complementary word-lines 208 to select the memory cell during storage operations, while the search driver 218 applies the bias voltages to the complementary search-lines 206 and the search-lines 208 during search operations. The bit decoder/data driver provides a RESET current pulse or a SET current pulse to the two memory elements in the individual memory cell 204 based on the resistance states that they need to be programmed to.

The search driver 218 provides the bias voltages to the individual complementary search-lines 206 and the search-lines 208 based on the resistance values that need to be searched in the memory cell 204. This horizontally oriented search may be attempting to locate a particular data word. The data word, however, as described above, may have been written in a particular column.

The plurality of match-lines 210 are electrically coupled to the bit decoder/data driver 216, and the match circuit 212. In one embodiment of the invention the match circuit 212 applies a positive voltage to the plurality of match-lines 410 during search operations. As described above, during search operations, a match is indicated between a data word and a search word by the match circuit 212 if an individual match-line 210 has a collective current below a threshold value. In an alternate embodiment of the invention, a match is indicated between a data word and search word by the match circuit 212 if an individual match-line 210 has a collective resistance above a threshold value. If any number of memory cells of the plurality of memory cells 204 electrically coupled in series to an individual match-line 110 has a mismatch, a match is not indicated. If a match between the data word and search word is determined, a word location (the address of the specific matching match-line) is outputted.

Data to be stored in the memory array 220 is typically received as a data word. For example, a data word of “0110” may be received. To store this data word into memory array 220 in such a way that may be easily read, the entire word needs arranged such that all bits are coupled to a single match-line 210. Thus, and as shown in FIG. 2, the data words are stored vertically oriented along a single match-line. For example, the data word “0110” is stored in the memory array 220 in the cells coupled to match-line M1. However, because all of the cells share the same match-line M1, each cell must be written separately. This requires, for an M×N array, M×2N write cycles to write all of the cells of the memory array 220 because each cell, as described above, requires two write cycles to program both of the resistive elements contained therein.

The perpendicular nature of the lines write (206 and 208) and the match lines 210 is just one example of how the memory array 220 may be implemented in silicon and is not required. As such, the term perpendicular, as used herein with respect the writing and searching, shall include other orientations that have the write lines one orientation and match lines in another.

In one embodiment of the present invention, data to be stored in a CAM or ternary CAM is first stored to transposable memory. Words are then read out of the transposable memory and provided to the CAM (or ternary CAM) transposed such that the previously horizontally oriented words are written into the CAM vertically. Of course, if the orientation of the match lines and word write lines are reverses from that shown in FIG. 2 (i.e., the match lines 210 are horizontally oriented and the write word lines 206 and 208 are vertically oriented) then horizontally oriented words may be vertically oriented in the memory.

In more detail, embodiment of the present invention may utilize a transposable memory array to prepare received data for storage in a CAM or ternary CAM. It will be understood that while the present invention has been described with respect to a particular PCM CAM, the teachings herein could be applied to any type of resistance change memory. The transposable memory transposes the input words from a horizontal to a vertical orientation. Each transposed word output that is received may then be stored in a particular row of the CAM. The CAM may be programmed row by row because each column has a separate match lines. Thus, to write an M×N array according to this embodiment requires 2M write cycles.

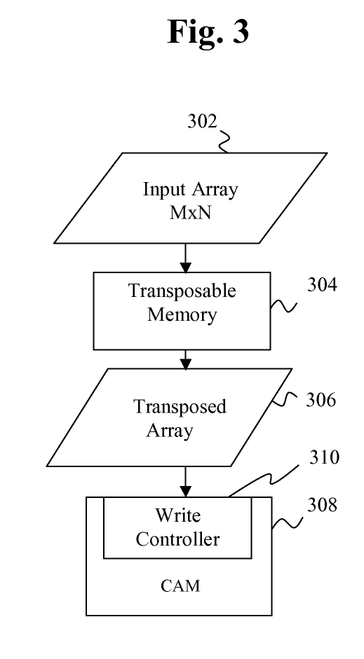

FIG. 3 shows a data flow diagram for a system according to an embodiment of the present invention. An input array 302 defines the data that is to be stored in the CAM 308. This input array 302 may be, for example, a series of identifiers for particular individuals or a series of Internet Protocol (IP) addresses for computers that may have access to a particular system. The CAM 308 may be used, for example, to quickly determine if a particular individual or user is allowed to access certain information.

The input array may have M entries, each of which are N bits wide. An example of such an input where M=3 and N=4 may be represented as follows:

$$\begin{matrix}0 & 1 & 1 & 0 \\ X & 1 & X & 1 \\ 1 & 0 & 1 & X\end{matrix}$$

In the above matrix, the bottom row may be referred to as word line 1, the middle row as word line 2 and the top row as word line 3. Of course, there could be M word lines. Similarly, the columns, from left to right may be referred to as bit line 1 to bit line N.

Referring back to FIG. 3, the input array 302 may be written into the transposable memory 304 word line by word line so that the transposable memory 304 contains, for example, a matrix as shown above. In general a transposable memory is a device (or software construct) that allows for data be stored in one manner and accessed in another. In one embodiment the transposable memory 304 may be a register file. In a particular embodiment, the transposable memory 304 may be written in a first manner by word line, bit line addressing and accessed in a second manner by transposed word line, transposed bit line addressing where the bit line and the transposed word line have the same value and the word line and the transposed bit line have the same value.

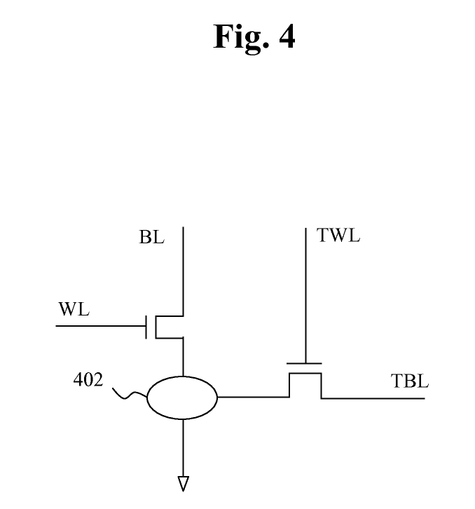

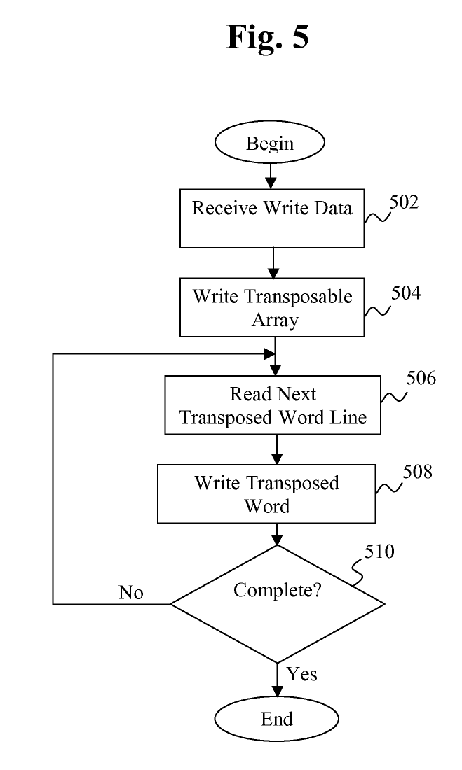

FIG. 4 shows an example of a cell 400 that may form a portion of a transposable memory. The cell 400 includes a storage node 402. The storage node 402 may be any type of storage device. For example, the storage node 402 may be eDRAM, SRAM, or PCM based. Regardless, for writing a value to the storage node 402 it may be accessed by the bit line BL and the word line WL. To read from the storage node 402 the storage node may be addressed by the transposed word line TWL and the transposed bit line. In this manner, for example, a bit stored in row 2, bit 3, would be accessed as if it were located in row 3, bit 2.

Referring now back to FIG. 3, the transposable memory 304 may be read from such that the output thereof forms a transposed array 306. In particular, the reading transverse word line 1, followed by transverse word line 2, etc., would create a matrix from the matrix shown above that may be represented as shown below:

$$\begin{matrix}0 & 1 & X \\ 1 & X & 1 \\ 1 & 1 & 0 \\ 0 & X & 1\end{matrix}$$

In this arrangement, the transposed array 306 is provided to the CAM 308. A write controller 310 may read a word from the transposed array and then write that word to the CAM 308 with only two write cycles. For example, the first word “0X1” could be written at a first write line pair of the CAM 308, and the second word “110” could be written at a second write line pair of the CAM 308. In one embodiment, the CAM 308 may include a write head coupled to each match line. Each write head receives a bit of the word (transposed by the transposable memory 304) and causes it to be driven on to the match line.

After writing the CAM 308 an input word may be received and compared to the contents of the CAM 308. As will be apparent to one of skill in the art, writing the CAM 308 as described above arranges all of the bits of a word along a single match line and allows for significant decrease in the number of write cycles required to write the CAM 308 as compared to having to write each cell of the CAM 308 individually.

It shall be understood that the transposable memory could be single memory that provides write data to one or more sub-array of the CAM 308. Of course, in one embodiment, in the event the CAM 308 includes sub-arrays. Each sub-array could include its own transposable memory associated therewith. Such a configuration may allow for the sub-arrays to be written in parallel but may require more space than utilizing a single transposable memory.

FIG. 5 is a flow chart of a method of writing a CAM according to one embodiment of the present invention. At a block 502 write data is received. The write data may be received as an M×N array and is received at a write controller for a transposable array.

At a block 504 the transposable array is written. The write controller causes a first word line to be written horizontally with an N-bit word. The write controller then causes a different second word line to written horizontally. This process may be performed until the write data is completely stored in the transposable array. In short, at block 404 M word lines are written to the transposable array with each line being N bits wide.

At a block 506, the next (starting with the first) transposed word line is read from the transposable array. The reading may be done, for example, by a write controller of a CAM.

At a block 508 the transposed word line (which is M bits wide) is written to the CAM. In particular, such writing writes the transposed word line at word write line 1 in the first instance and then writes the next transposed word line at word write line 2 and so on.

At a block 510 it is determined if the writing is complete. This may be done, for example, by determining that N words have been written to the CAM. If the writing is not complete, the method returns to block 406 where the next transposed word line is read. Otherwise, the process ends.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one ore more other features, integers, steps, operations, element components, and/or groups thereof.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated

The flow diagrams depicted herein are just one example. There may be many variations to this diagram or the steps (or operations) described therein without departing from the spirit of the invention. For instance, the steps may be performed in a differing order or steps may be added, deleted or modified. All of these variations are considered a part of the claimed invention.

While the preferred embodiment to the invention had been described, it will be understood that those skilled in the art, both now and in the future, may make various improvements and enhancements which fall within the scope of the claims which follow. These claims should be construed to maintain the proper protection for the invention first described.

What is claimed is:

1. A memory system for storing one or more addresses, the memory system comprising:
a transposable memory having word lines, bit lines, transposed word lines and transposed bit lines and that receives and stores an input array having dimensions M by N; and
a content addressable memory (CAM) that reads the transposed word lines of the transposable memory to form input words and that stores the input words in an N by M array.

2. The memory system of claim 1, wherein the transposable memory is formed by an eDRAM transposable array.

3. The memory system of claim 1, wherein the transposable memory array is formed by an SRAM transposable array.

4. The memory system of claim 1, wherein the transposable memory is a register file.

5. The memory system of claim 1, wherein the transposable memory is formed by a phase change material transposable memory.

6. The memory system of claim 1, wherein the CAM is a ternary CAM.

7. The memory system of claim 1, wherein the CAM includes memory cells formed of at least one phase change material memory element.

8. The memory system of claim 7, wherein the memory cells are formed of two or more phase change material memory elements.

9. The memory system of claim 8, wherein each cell is connected to one match line and two word write lines.

10. The memory system of claim 9, wherein the match line and the write lines are perpendicular to each other.

11. The memory system of claim of claim 1, wherein the CAM includes a write controller that reads a row of the transposable array and causes it to be stored as a column in the CAM.

12. A method of writing a content addressable memory, the method comprising:
storing input data in a transposable array, each word of the input data being stored in along a word line;
reading a first transposed word line of the transposable array to create a transposed first data word; and
storing each bit of the first transposed data word in a separate memory cell of plurality of memory cells arranged along a first write line of the content addressable memory.

13. The method of claim 12, wherein storing the transposed data word includes two write cycles, the first selecting a first storage element of a cell in the CAM and the second selecting a second storage element of the cell.

14. The method of claim 12, wherein storing the input data includes receiving and M by N array and storing the M by N array in the transposable memory.

15. The method of claim 12, further comprising:
reading a second transposed word line of the transposable array to create a second transposed data word; and
storing each bit of the second transposed data word in a separate memory cell of plurality of memory cells arranged along a second write line of the CAM.

16. The method of claim 12, wherein the CAM is a ternary CAM.

17. A method of operating a content addressable memory (CAM), the method comprising:
storing input data in a transposable array;
accessing the transposable array to receive a transposed input data array; and
storing the transposed input data array in the CAM a word at a time.

18. The method of claim 17, further comprising:
comparing an search input to a column of the CAM.

19. The method of claim 17, wherein accessing includes retrieving bits stored along a first transverse word line of the transposable array and wherein storing includes storing the bits stored along the first transverse word line of the transposable array along a first word write line of the CAM.

20. The method of claim 17, wherein accessing includes retrieving bits stored along a second transverse word line of the transposable array and wherein storing includes storing the bits along the second transverse word line of the transposable array along a second word write line of the CAM.
